(19) United States
(12) Patent Application Publication
(10) Pub. No.: US 2024/0404939 A1
(43) Pub. Date: Dec. 5, 2024

(54) SEMICONDUCTOR DEVICE AND VEHICLE

(71) Applicant: FUJI ELECTRIC CO., LTD., Kawasaki-shi (JP)

(72) Inventors: Tsubasa NAKAMURA, Kawasaki-shi (JP); Daisuke INOUE, Kawasaki-shi (JP); Kengo INOUE, Kawasaki-shi (JP)

(73) Assignee: FUJI ELECTRIC CO., LTD., Kawasaki-shi (JP)

(21) Appl. No.: 18/649,311

(22) Filed: Apr. 29, 2024

(30) Foreign Application Priority Data
Jun. 5, 2023 (JP) 2023-092029

(51) Int. Cl. H01L 23/498; H01L 23/053; H01L 23/36

(52) U.S. Cl. CPC H01L 23/49844; H01L 23/053; H01L 23/36

(57) ABSTRACT

A semiconductor device, including a circuit board, a case member, and first and second main terminals each having an outer terminal portion and an inner terminal portion. The case member includes a terminal arrangement portion having a recess formed between the outer terminal portions of the first and second main terminals and extending in a direction from a first end to a second end thereof, the first end being closer to a housing portion of the case member than the second end, and than first end portions of the outer terminal portions of the main terminals, and the second end being farther from the housing portion than second end portions of the outer terminal portion of the main terminals. A protrusion is formed on a wall surface of the terminal arrangement portion toward the housing portion, and is aligned with the recess and separates the recess and the housing portion.

### CROSS-REFERENCE TO RELATED APPLICATION

This application is based upon and claims the benefit of priority to Japanese Patent Application No. 2023-092029, filed on Jun. 5, 2023, the entire contents of which are incorporated herein by reference.

### BACKGROUND OF THE INVENTION

### 1. Technical Field

The present invention relates to a semiconductor device and a vehicle.

### 2. Description of the Related Art

A semiconductor device used in a power conversion device such as an inverter device includes a case that houses an interconnect plate on which a semiconductor element is mounted. The case includes an insulating case member and a plurality of terminals electrically connected to electrodes of the semiconductor element (for example, JP 01-144662A, JP 2002-164503A, JP 2014-183196A, and JP 09-232512A).

### SUMMARY OF THE INVENTION

In the case of the semiconductor device described above, it is difficult to further downsize the semiconductor device while ensuring the insulation that depends on the creepage distance between two main terminals, which have different applied potentials.

The present invention has been made in view of such a point, and an object of the present invention is to enable further miniaturization of a semiconductor device while ensuring insulation that depends on the creepage distance.

A semiconductor device according to one aspect of the present invention includes: a circuit board in which a semiconductor element is disposed on an interconnect plate; a case member having a housing portion in which the circuit board is housed; and a plurality of main terminals each having an outer terminal portion exposed to a terminal arrangement portion of the case member and an inner terminal portion electrically connected to a conductor of the circuit board in the housing portion of the case member, in which the case member has a shape in which the terminal arrangement portion and the housing portion are adjacent to each other in a plan view of a first surface of the terminal arrangement portion on which the outer terminal portion is disposed, the plurality of main terminals includes: a first main terminal and a second main terminal, the outer terminal portions of which are arranged with a predetermined gap in a first direction along a boundary between the terminal arrangement portion and the housing portion in a plan view of the first surface of the case member, and the terminal arrangement portion of the case member includes a recess that is displaced from the first surface in a direction of a second surface opposite to the first surface between the outer terminal portion of the first main terminal and the outer terminal portion of the second main terminal in the first surface, and extends in a second direction different from the first direction in a plan view of the first surface, and one end of the recess in the second direction being located closer to the housing portion than an end portion of the outer terminal portion of the first main terminal and an end portion of the outer terminal portion of the second main terminal, which are close to the housing portion, the other end of the recess in the second direction being located farther from the housing portion than an end portion of the outer terminal portion of the first main terminal and an end portion of the outer terminal portion of the second main terminal, which are far from the housing portion; and a protrusion that protrudes toward the housing portion at a position obtained by extending the one end of the recess in a wall surface facing the housing portion in the second direction and separates the recess and the housing portion.

According to the present invention, it is possible to further downsize the semiconductor device while ensuring the insulation that depends on the creepage distance.

### BRIEF DESCRIPTION OF THE DRAWINGS

FIG. 1 is a top view illustrating a configuration example of a semiconductor device according to an embodiment;

FIG. 2 is an enlarged top view of a configuration of one circuit formation portion in the semiconductor device of FIG. 1;

FIG. 3 is a cross-sectional side view illustrating a configuration example of the semiconductor device taken along line A-A′ in FIG. 2;

FIG. 4 is a diagram illustrating a circuit configuration example of an inverter device to which the semiconductor device in FIG. 1 is applied;

FIG. 5 is a perspective view for illustrating an example of a method for ensuring insulation between outer terminal portions in a case according to one embodiment;

FIG. 6 is a top view illustrating a first example of a shape of a recess between the outer terminal portions;

FIG. 7 is a front view illustrating the first example of the shape of the recess between the outer terminal portions;

FIG. 8 is a cross-sectional side view illustrating the first example of the shape of the recess in the case taken along line B-B′ in FIG. 6;

FIG. 9 is a perspective view illustrating a conventional example of a case in which a creepage distance is increased;

FIG. 10 is a front view of a portion of the case illustrated in FIG. 9;

FIG. 11 is a top view for illustrating a first modification of the recess;

FIG. 12 is a top view for illustrating a second modification of the recess;

FIG. 13 is a top view for illustrating a third modification of the recess;

FIG. 14 is a top view for illustrating a fourth modification of the recess;

FIG. 15 is a side cross-sectional view for illustrating another modification of the recess;

FIG. 16 is a front view illustrating still another modification of the recess; and

FIG. 17 is a schematic plan view illustrating an example of a vehicle to which the semiconductor device according to the present invention is applied.

### DETAILED DESCRIPTION

Hereinafter, an embodiment of the present invention will be described in detail with reference to the drawings. Note that the X axis, the Y axis, and the Z axis in each of the drawings to be referred to are illustrated for the purpose of defining a plane and a direction in the exemplified semiconductor device or the like. The X, Y, and Z axes are orthogonal to each other and form a right-handed system. In the following description, a direction parallel to the X axis is referred to as an X direction, a direction parallel to the Y axis is referred to as a Y direction, and a direction parallel to the Z axis is referred to as a Z direction. In addition, in a case where each of the X direction, the Y direction, and the Z direction is associated with a direction of an arrow (positive or negative) of the X axis, the Y axis, and the Z axis illustrated, a “positive side” or a “negative side” is attached.

In the present specification, the Z direction may be referred to as a vertical direction. In the present specification, “up” and “upper” are intended to be on the positive side in the Z direction with respect to the reference surface, member, position, and the like, and “down” and “lower” are intended to be on the negative side in the Z direction with respect to the reference surface, member, position, and the like. For example, when it is described that “the member B is disposed on the member A”, the member B is disposed on the positive side in the Z direction as viewed from the member A. Further, when the “upper surface of the member A” is described, the surface is located at the end of the member A on the positive side in the Z direction and faces the positive side in the Z direction. In the present specification, “top view” is intended as a plan view when a target article (for example, a semiconductor device or the like) is viewed from the positive side in the Z direction. In the present specification, the term “front view” is intended as a plan view when a target article is viewed from the negative side in the Y direction. In the present specification, the “side view” is intended as a plan view when a target article is viewed from the negative side in the X direction or the positive side in the X direction, and the plan view when viewed from the negative side in the X direction may be referred to as a “left side view”, and the plan view when viewed from the positive side in the X direction may be referred to as a “right side view”. Such directions and surfaces are terms used for convenience of description. Thus, depending on a posture of attachment of the semiconductor device, a correspondence relationship with directions of the X, Y, and Z axes may vary. For example, a surface of the case member on which an outer terminal portion of a main terminal is disposed is referred to as an upper surface of the case member in the present specification, but is not limited thereto, and may be referred to as a lower surface, a side surface, or the like of the case member. Furthermore, an aspect ratio and a magnitude relationship between the members in each drawing are merely schematically represented, and do not necessarily coincide with a relationship in a semiconductor device or the like actually manufactured. A case in which the magnitude relationship between the members is exaggerated for convenience of description is also assumed.

Furthermore, the semiconductor device to be described in the following description may be applied to, for example, a power conversion device such as an industrial or electrical (for example, an in-vehicle motor) inverter device. Thus, in the following description, detailed description of the same or similar configuration, function, operation, manufacturing method, and the like as those of the known semiconductor device will be omitted.

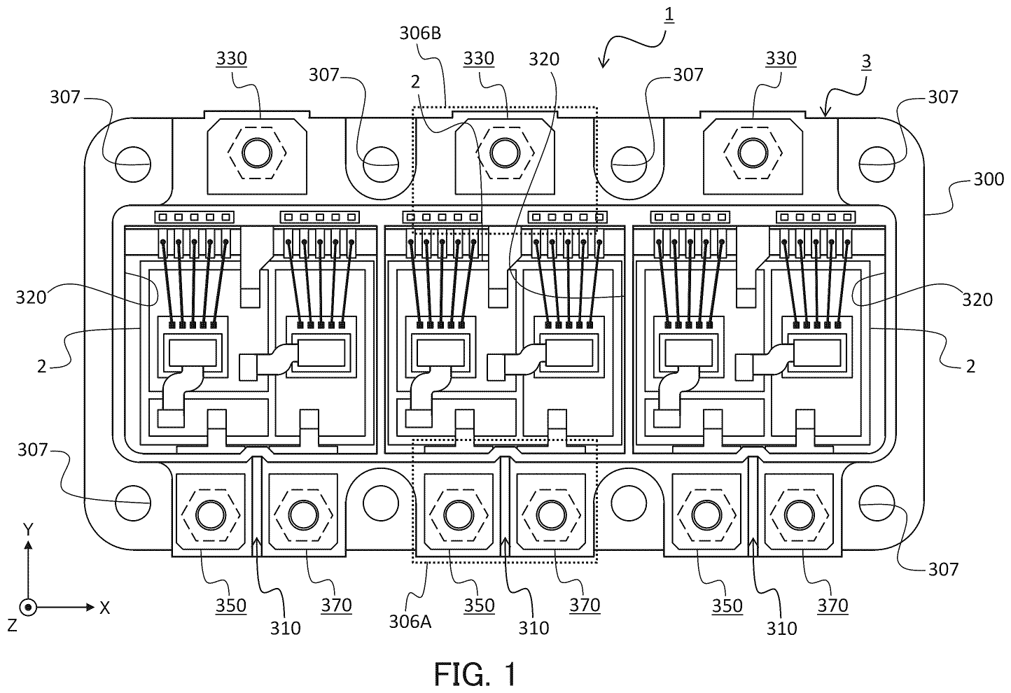

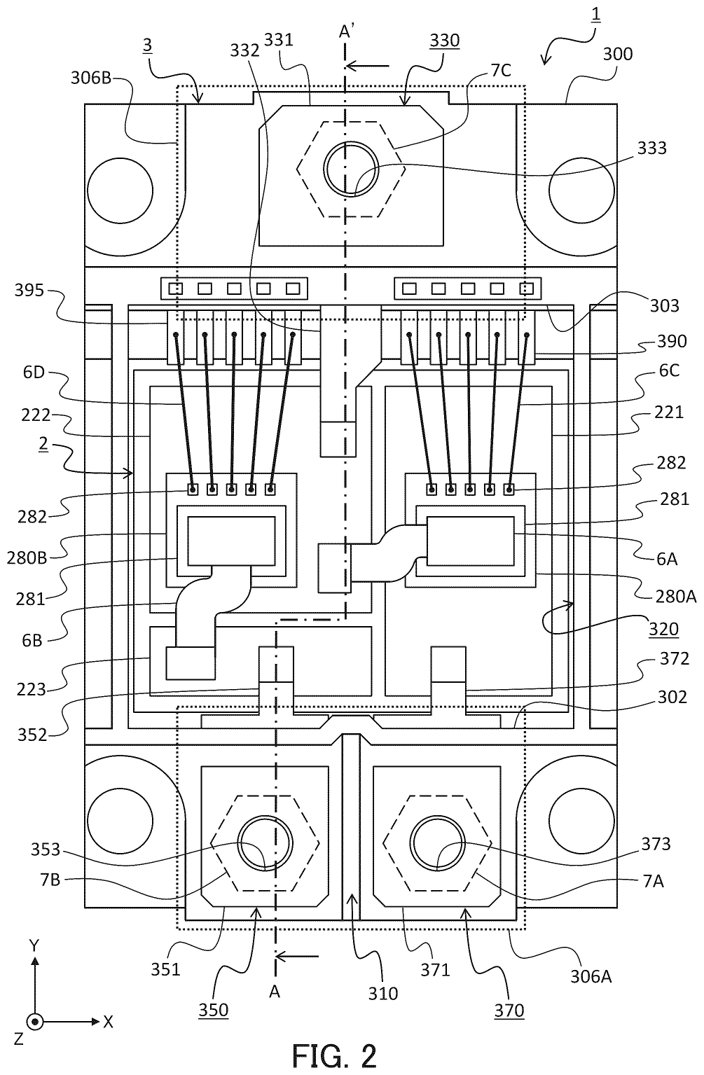

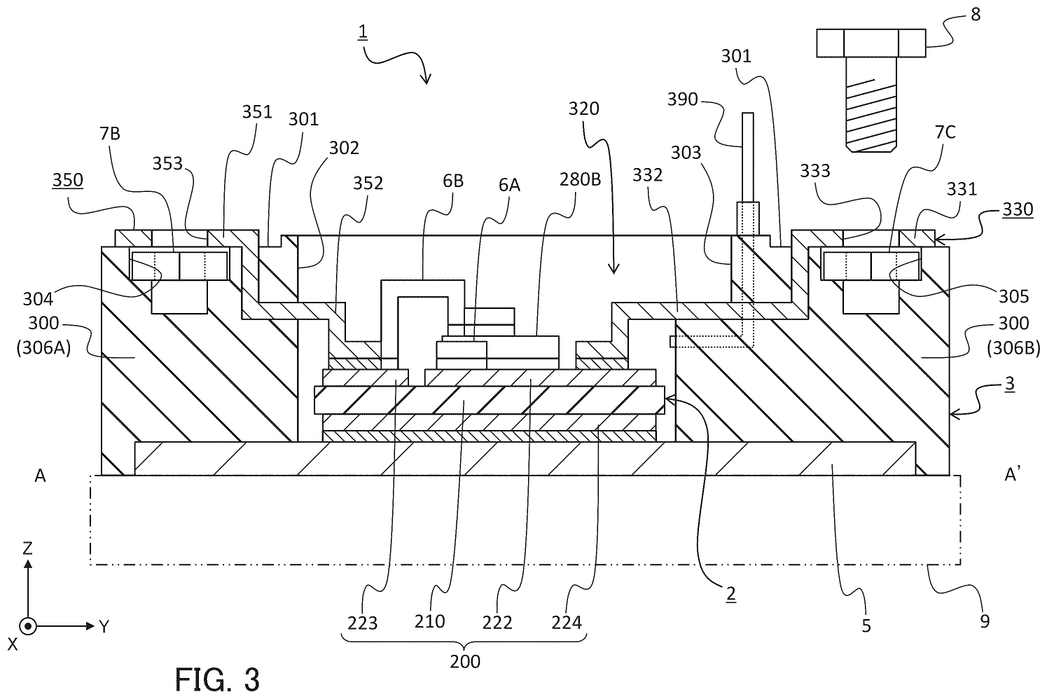

FIG. 1 is a top view illustrating a configuration example of a semiconductor device according to an embodiment. FIG. 2 is an enlarged top view of a configuration of one circuit formation portion in the semiconductor device of FIG. 1. FIG. 3 is a cross-sectional side view illustrating a configuration example of the semiconductor device taken along line A-A′ in FIG. 2. The top view of FIG. 2 illustrates a central circuit formation portion among three circuit formation portions aligned in the X direction in the semiconductor device of FIG. 1. The cross-sectional side view of FIG. 3 illustrates a right side view of a portion of the semiconductor device taken along line A-A′ of FIG. 2 on the left side of line A-A′. In FIGS. 1 to 3, illustration of a sealing material for sealing a semiconductor element or the like is omitted.

A semiconductor device 1 illustrated in FIGS. 1 to 3 includes a circuit board 2, a case 3, and a heat dissipation base 5.

In the exemplified semiconductor device 1, three circuit boards 2 are arranged on an upper surface of the heat dissipation base 5. The three circuit boards 2 have substantially the same configuration and include an interconnect plate 200 and two semiconductor elements 280A and 280B disposed on an upper surface of the interconnect plate 200. The number of circuit boards 2 disposed on the upper surface of heat dissipation base 5 is not limited to three. The number of semiconductor elements disposed on the upper surface of one interconnect plate 200 is not limited to two.

The interconnect plate 200 includes an insulating substrate 210, conductor patterns 221 to 223 provided on an upper surface of the insulating substrate 210, and a conductor pattern 224 provided on a lower surface of the insulating substrate 210. The interconnect plate 200 may be, for example, a Direct Copper Bonding (DCB) substrate or an Active Metal Brazing (AMB) substrate. The interconnect plate 200 may be referred to as a stacked substrate, an insulating circuit substrate, or the like.

The insulating substrate 210 is not limited to a specific substrate. The insulating substrate 210 may be, for example, a ceramic substrate made of a ceramic material such as aluminum oxide (Al₂O₃), aluminum nitride (AlN), silicon nitride (Si₃N₄), or a composite material of aluminum oxide (Al₂O₃) and zirconium oxide (ZrO₂). The insulating substrate 210 may be, for example, a substrate obtained by molding an insulating resin such as epoxy resin, a substrate obtained by impregnating a base material such as a glass fiber with an insulating resin, a substrate obtained by coating a surface of a flat plate-shaped metal core with an insulating resin, or the like.

The conductor patterns 221 to 223 provided on the upper surface of the insulating substrate 210 function as a wiring component, and is formed of, for example, a metal plate such as copper or aluminum, a metal foil, or the like. The conductor patterns 221 to 223 provided on the upper surface of the insulating substrate 210 may be referred to as conductor layers, conductor plates, conductive layers, wiring patterns, or the like. In the following description, in a case where the conductor patterns 221 to 223 are distinguished from each other, the conductor patterns 221 to 223 are respectively written as a first conductor pattern 221, a second conductor pattern 222, and a third conductor pattern 223.

Each of the two semiconductor elements 280A and 280B disposed on the upper surface of the interconnect plate 200 includes, for example, a reverse conducting (RC)-insulated gate bipolar transistor (IGBT) element in which an IGBT element that is a switching element and a function of a diode element such as a free wheeling diode (FWD) element connected in antiparallel to the IGBT element are integrated. In each of the semiconductor elements 280A and 280B of this type, a first main electrode (not illustrated) is provided on the lower surface, and a second main electrode 281 and a control electrode (gate electrode) 282 are provided on the upper surface. When the switching elements of the semiconductor elements 280A and 280B are IGBT elements, the first main electrode on the lower surface side may be referred to as a collector electrode, and the second main electrode 281 on the upper surface side may be referred to as an emitter electrode. In addition, the substrate on which the switching elements and the diode elements of the semiconductor elements 280A and 280B are formed is not limited to the silicon substrate, and may be, for example, a silicon carbide (SiC) substrate, a gallium nitride (GaN) substrate, or the like.

In the example of FIG. 2, the semiconductor element 280A is disposed on the upper surface of the first conductor pattern 221, and the semiconductor element 280B is disposed on the upper surface of the second conductor pattern 222. The first conductor pattern 221 is bonded to the first main electrode (not illustrated) provided on a lower surface of the semiconductor element 280A with a bonding material (not illustrated). The bonding material may be a known bonding material such as solder. Further, the second conductor pattern 222 is bonded to the first main electrode (not illustrated) provided on a lower surface of the semiconductor element 280B with the bonding material (not illustrated).

The first main electrode provided on the lower surface of the semiconductor element 280A is electrically connected to a first main terminal 370 provided in the case 3 via the first conductor pattern 221. The first conductor pattern 221 and the first main terminal 370 are bonded to each other by a known bonding material (not illustrated) such as solder. The second main electrode 281 provided on the upper surface of the semiconductor element 280A is electrically connected to the second conductor pattern 222 via a wiring component 6A. The wiring component 6A is formed by bending a conductor plate such as a copper plate, and is called a lead, a lead frame, or the like. A part of the wiring component 6A is bonded to second main electrode 281 of semiconductor element 280A by a known bonding material (not illustrated) such as solder, and another part is bonded to the second conductor pattern 222 by a known bonding material (not illustrated) such as solder. The control electrode 282 provided on the upper surface of the semiconductor element 280A is electrically connected to a control terminal 390 provided on the case 3 by a bonding wire (wiring component 6C).

The first main electrode provided on the lower surface of the semiconductor element 280B is electrically connected to a third main terminal 330 provided in the case 3 via the second conductor pattern 222. The second conductor pattern 222 and the third main terminal 330 are bonded to each other by a known bonding material (not illustrated) such as solder. The second main electrode 281 provided on the upper surface of the semiconductor element 280B is electrically connected to the second main terminal 350 provided on the case 3 via the wiring component 6B and the third conductor pattern 223. The wiring component 6B is formed by bending a conductor plate such as a copper plate, and is called a lead, a lead frame, or the like. A part of wiring component 6B is bonded to second main electrode 281 of semiconductor element 280B by a known bonding material (not illustrated) such as solder, and another part is bonded to the third conductor pattern 223 by a known bonding material (not illustrated) such as solder. The control electrode 282 provided on the upper surface of the semiconductor element 280B is electrically connected to a control terminal 395 provided on the case 3 by a bonding wire (wiring component 6D).

Note that the method of electrically connecting two conductive members in the semiconductor device 1 may be a method different from the above-described method. For example, the electrical connection between the first conductor pattern 221 of the interconnect plate 200 and the first main terminal 370 of the case 3, the electrical connection between the second conductor pattern 222 and the third main terminal 330, and the electrical connection between the third conductor pattern 223 and the second main terminal 350 may be performed by laser welding, ultrasonic bonding, or the like. For example, one or both of the wiring component 6A electrically connected to second main electrode 281 of the semiconductor element 280A and the wiring component 6B electrically connected to the second main electrode 281 of the semiconductor element 280B may be a bonding wire.

The conductor pattern 224 provided on the lower surface of the insulating substrate 210 functions as a heat conducting member that conducts heat generated by the semiconductor elements 280A and 280B to the heat dissipation base 5, and is formed of, for example, a metal plate, a metal foil, or the like such as copper or aluminum. The heat dissipation base 5 may be a part of a cooler 9 (see FIG. 3) disposed below heat dissipation base 5, or may be a heat conducting member attached to the cooler 9 and different from the cooler 9. The conductor pattern 224 is bonded to the upper surface of the heat dissipation base 5 with a bonding material (not illustrated) such as solder. The conductor pattern 224 may be referred to as a heat dissipation layer or a heat dissipation pattern. In the semiconductor device 1 according to the present embodiment, the cooler 9 has any configuration.

The case 3 includes a case member 300 having a housing portion 320 capable of housing the circuit board 2 and the wiring components 6A to 6D disposed on the upper surface of the heat dissipation base 5, the first main terminal 370, the second main terminal 350, the third main terminal 330, the control terminal 390, and the control terminal 395 described above. This type of case 3 is manufactured by a known manufacturing method such as a method using insert molding.

The case member 300 of the case 3 illustrated in FIGS. 1 to 3 has a schematic annular shape having three housing portions (hollow portions) 320 whose upper and lower ends are opened, and one circuit board 2 is housed in one housing portion 320. A set including the first main terminal 370, the second main terminal 350, the third main terminal 330, the control terminal 390, and the control terminal 395 described above is provided in the case member 300 for each circuit board 2 housed in the housing portion 320 of the case member 300.

Each of the first main terminal 370, the second main terminal 350, and the third main terminal 330 includes an outer terminal portion exposed to the terminal arrangement portion of the case member 300 and an inner terminal portion electrically connected to the conductor of the circuit board 2 in the housing portion 320 of the case member 300. For example, as illustrated in FIG. 3, the second main terminal 350 includes an outer terminal portion 351 disposed along the upper surface 301 of the terminal arrangement portion 306A, and an inner terminal portion 352 extending from the wall surface 302 of the terminal arrangement portion 306A facing the housing portion 320 into the housing portion 320. An intermediate portion (not illustrated) between the outer terminal portion 351 and the inner terminal portion 352 is embedded in the case member 300 (terminal arrangement portion 306A). The outer terminal portion 351 is disposed on the upper surface 301 by bending a flat plate-like portion protruding upward from the upper surface 301 of the terminal arrangement portion 306A along the upper surface 301. After a nut 7B is fitted into a nut hole 304 formed in the upper surface 301 of the terminal arrangement portion 306A, the outer terminal portion 351 in the semiconductor device 1 of the present embodiment is bent so as to cover the nut hole 304 and is disposed along the upper surface 301. An opening 353 overlapping with the screw hole of the nut 7B is formed in the outer terminal portion 351. The inner terminal portion 352 of the second main terminal 350 is electrically connected to the third conductor pattern 223 of the interconnect plate 200.

The first main terminal 370 includes an outer terminal portion 371 and an inner terminal portion 372, and an intermediate portion (not illustrated) between the outer terminal portion 371 and the inner terminal portion 372 is embedded in the terminal arrangement portion 306A. The outer terminal portion 371 of the first main terminal 370 is disposed along the upper surface 301 of the terminal arrangement portion 306A so as to be adjacent to the outer terminal portion 351 of the second main terminal 350 with a predetermined gap. The outer terminal portion 371 of the first main terminal 370 covers a nut 7A (see FIG. 2) fitted into a nut hole (not illustrated) formed in the upper surface 301 of the terminal arrangement portion 306A, and an opening 373 overlapping with the screw hole of the nut 7A is formed. The inner terminal portion 372 of the first main terminal 370 extends from the wall surface 302 of the terminal arrangement portion 306A facing the housing portion 320 into the housing portion 320, and is electrically connected to the first conductor pattern 221 of the interconnect plate 200.

The third main terminal 330 includes an outer terminal portion 331 and an inner terminal portion 332, and an intermediate portion (not illustrated) between the outer terminal portion 331 and the inner terminal portion 332 is embedded in the terminal arrangement portion 306B located on the opposite side of the terminal arrangement portion 306A with the housing portion 320 interposed therebetween. The outer terminal portion 331 of the third main terminal 330 is disposed along the upper surface 301 of the terminal arrangement portion 306B. The outer terminal portion 331 of the third main terminal 330 covers a nut 7C fitted in the nut hole 305 formed in the upper surface 301 of the terminal arrangement portion 306B, and an opening 333 overlapping with the screw hole of the nut 7C is formed. The inner terminal portion 332 of the third main terminal 330 extends from the wall surface 303 of the terminal arrangement portion 306B facing the housing portion 320 into the housing portion 320, and is electrically connected to the second conductor pattern 222 of the interconnect plate 200.

The nuts 7A to 7C fitted into the nut holes of the case 3 are used, for example, to screw bolts 8 (see FIG. 3) for connecting the first main terminal 370, the second main terminal 350, and the third main terminal 330 to terminals of a power supply cable, a bus bar, and the like.

Each of the control terminal 390 and the control terminal 395 includes an outer terminal portion (not illustrated) extending upward from the upper surface 301 of the case member 300 (terminal arrangement portion 306B) and an inner terminal portion (not illustrated) extending from the wall surface 303 facing the housing portion 320 into the housing portion 320. In each of the control terminal 390 and the control terminal 395, an intermediate portion between the outer terminal portion and the inner terminal portion is buried in the case member 300. The number of control terminals 390 and the number of control terminals 395 are not limited to five illustrated in FIGS. 1 and 2. The number of control terminals 390 and the number of control terminals 395 are determined according to, for example, the number of control electrodes 282 of the semiconductor elements 280A and 280B. The control terminal 390 and the control terminal 395 are connected to a control circuit (not illustrated) that controls the operation of the circuit board 2.

The housing portion 320 of the case 3 is filled with a sealing material (not illustrated) for scaling the circuit board 2, the wiring components 6A to 6D, the main terminal of the case 3, the inner terminal portion of the control terminal, and the like. The sealing material is an epoxy resin, silicone gel, or the like, for example. The housing portion 320 of the case 3 may be formed as one housing portion without being divided for each circuit board 2 (that is, without being divided into three separate housing portions) as illustrated in FIG. 1.

For example, as illustrated in FIG. 1, the case member 300 of the case 3 has a plurality of hole forming portions in which a through hole 307 is formed, different from the above-described terminal arrangement portions 306A and 306B, at an outer edge portion in a top view. The case 3 is attached to the cooler 9 by, for example, screwing a bolt (not illustrated) inserted into the through hole 307 into a screw hole formed in the upper surface of the cooler 9. The heat dissipation base 5 is, for example, bonded to the lower surface of the case member 300 of the case 3, and comes into contact with the cooler 9 by attaching the case 3 to the cooler 9. The heat dissipation base 5 and the cooler 9 may be in close contact with each other via a heat conductive member such as thermal grease or thermal compound, for example. In addition, the heat dissipation base 5 may have a shape having a through hole at a position overlapping the through hole 307 of the case 3 in top view.

The semiconductor device 1 illustrated in FIG. 1 includes three single-phase inverter circuits, and can constitute, for example, a three-phase inverter device.

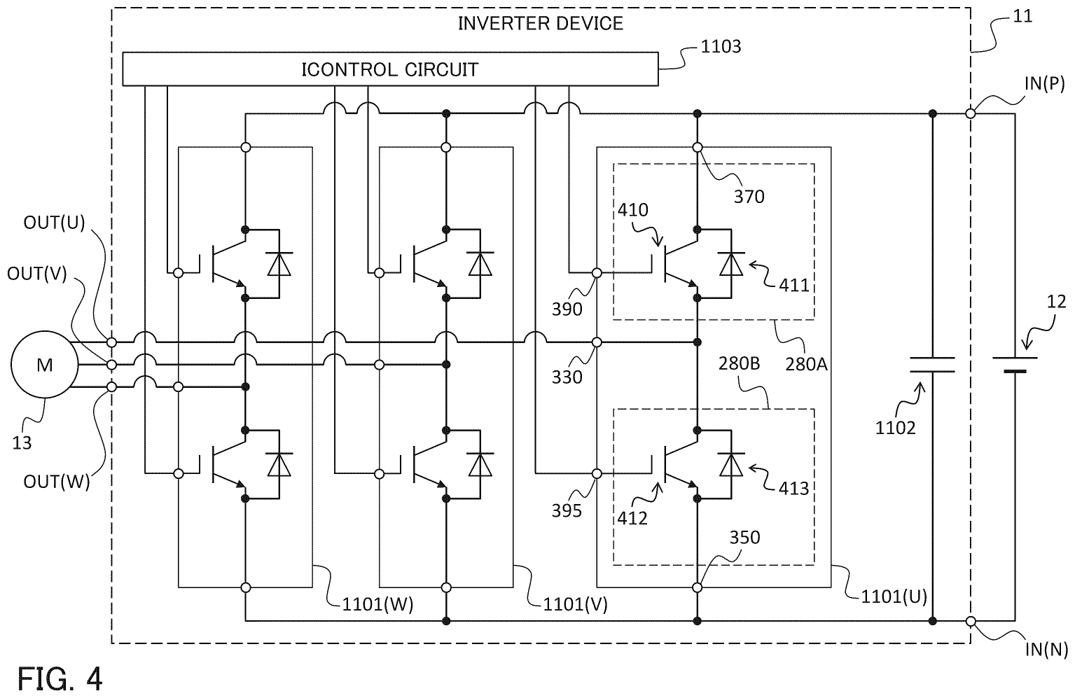

FIG. 4 is a diagram illustrating a circuit configuration example of an inverter device to which the semiconductor device in FIG. 1 is applied.

In FIG. 4, as an example of the inverter device 11, an example of a circuit configuration of a voltage-type three-phase inverter device is illustrated. The inverter device 11 includes three single-phase inverter circuits 1101 (U), 1101 (V), and 1101 (W), a smoothing capacitor 1102, and a control circuit 1103. The single-phase inverter circuit 1101 (U) converts a direct current into an alternating current and outputs the alternating current as a U-phase alternating current. The single-phase inverter circuit 1101 (V) converts a direct current into an alternating current and outputs the alternating current as a V-phase alternating current. The single-phase inverter circuit 1101 (W) converts a direct current into an alternating current and outputs the alternating current as a W-phase alternating current. Here, in the present specification, three phases in the three-phase alternating current are referred to as the U phase, the V phase, and the W phase. However, the three phases may be referred to as other terms.

In the inverter device 11, three single-phase inverter circuits 1101 (U), 1101 (V), and 1101 (W) and the smoothing capacitor 1102 are connected in parallel. The circuit configuration of each of the three single-phase inverter circuits 1101 (U), 1101 (V), and 1101 (W) illustrated as an equivalent circuit in FIG. 4 corresponds to the circuit formed using one circuit board 2 (a set of one interconnect plate 200 and two semiconductor elements 280A and 280B) in the semiconductor device 1 described above with reference to FIGS. 2 and 3.

The inverter device 11 includes a first input end IN (P) that is connected to a positive electrode of a direct current power supply 12, a second input end IN (N) that is connected to a negative electrode of the direct current power supply 12, and output ends OUT (U), OUT (V), and OUT (W) that output three-phase alternating currents. The first input end IN (P) is connected to the first main terminal 370 of the semiconductor device 1, and the second input end IN (N) is connected to the second main terminal 350 of the semiconductor device 1. The output ends OUT (U), OUT (V), and OUT (W) are connected to the third main terminal 330 of the semiconductor device 1.

Each of the single-phase inverter circuits 1101 (U), 1101 (V), and 1101 (W) illustrated in FIG. 4 is a half-bridge inverter circuit. In the single-phase inverter circuit 1101 (U), a collector electrode of the switching element 410 (for example, an IGBT element) in the semiconductor element 280A connected between the first input end IN (P) and the output end OUT (U), which may be referred to as an upper arm, is connected to the first input end IN (P) via the first main terminal 370. Further, in the single-phase inverter circuit 1101 (U), an emitter electrode of the switching element 412 in the semiconductor element 280B connected between the second input end IN (N) and the output end OUT (U), which may be referred to as a lower arm, is connected to the second input end IN (N) via the second main terminal 350. The emitter electrode of the switching element 410 of the upper arm and the collector electrode of the switching element 412 of the lower arm in the single-phase inverter circuit 1101 (U) are connected to the output end OUT (U) that outputs the U-phase alternating current in the three-phase alternating currents via the third main terminal 330. The diode element 411 is connected in reverse parallel to the switching element 410 of the upper arm, and the diode element 413 is connected in reverse parallel to the switching element 412 of the lower arm. The other two single-phase inverter circuits 1101 (V) and 1101 (W) have a configuration in which the output ends OUT (U) in the single-phase inverter circuit 1101 (U) described above are replaced with output ends OUT (V) and OUT (W), respectively.

Alternating currents output from the single-phase inverter circuits 1101 (U), 1101 (V), and 1101 (W) are controlled by a control signal applied from the control circuit 1103 to the gate of the switching element 410 of the upper arm (the control electrode 282 of the semiconductor element 280A) via the control terminal 390 and a control signal applied to the gate of the switching element 412 of the lower arm (the control electrode 282 of the semiconductor element 280B) via the control terminal 395 such that the phases are shifted from each other by 120 degrees. The output ends OUT (U), OUT (V), and OUT (W) of the inverter device 11 are connected to a load (for example, AC motor) 13 that operates with an alternating current.

Note that the circuit configuration of the inverter device 11 including the semiconductor device 1 of the present embodiment is not limited to the circuit configuration illustrated in FIG. 4. In addition, the operation of the inverter device 11 including the semiconductor device 1 of the present embodiment is also not limited to a specific operation. For example, in the inverter device 11 including the semiconductor device 1, three single-phase full-bridge inverter circuits may be connected in parallel.

Moreover, the inverter device 11 described above with reference to FIG. 4 is merely an example of a device to which the semiconductor device 1 according to the present embodiment is applied.

The switching elements 410 and 412 of the semiconductor elements 280A and 280B are not limited to the IGBT element described above, and may be configured by, for example, a power metal oxide semiconductor field effect transistor (MOSFET), a bipolar junction transistor (BJT), or the like. When the switching element is a MOSFET element, the main electrode on the lower surface side of each of the semiconductor elements 280A and 280B may be referred to as a drain electrode, and the main electrode 281 on the upper surface side may be referred to as a source electrode. Furthermore, the diode elements 411 and 413 may include, for example, a Schottky barrier diode (SBD), a junction barrier Schottky (JBS) diode, a merged PN Schottky (MPS) diode, a PN diode, or the like. Furthermore, the control electrodes 282 provided on the upper surfaces of the semiconductor elements 280A and 280B may include a gate electrode and an auxiliary electrode. For example, the auxiliary electrode may be an auxiliary emitter electrode or an auxiliary source electrode electrically connected to the main electrode on the upper surface side and serving as a reference potential with respect to a gate potential. Furthermore, the auxiliary electrode may be a temperature sensing electrode that is electrically connected to a temperature sensing unit that may be included in an inverter device 11 or the like and measures temperatures of the semiconductor elements 280A and 280B. These electrodes (second main electrode 281 and control electrode 282 including gate electrode and auxiliary electrode) formed on the upper surfaces of the semiconductor elements 280A and 280B may be collectively referred to as upper surface electrodes. Furthermore, a substrate on which the switching elements 410 and 412 and the diode elements 411 and 413 are formed is not limited to a silicon substrate, and may be, for example, a silicon carbide (SiC) substrate, a gallium nitride (GaN) substrate, or the like.

In addition, the switching element and the diode element described as being included in one semiconductor element in the single-phase inverter circuit described above with reference to FIG. 4 may be provided by separate semiconductor elements. For example, the switching element 410 and the diode element 411 of the upper arm may be provided by a semiconductor element in which the switching element 410 is formed and a semiconductor element in which the diode element 411 is formed. The shape, arrangement number, arrangement location, and the like of the semiconductor element can appropriately be changed. The layout of the conductor pattern as the wiring component provided on the upper surface side of the interconnect plate 200 is changed according to the type and shape of the semiconductor element, the number of the semiconductor elements to be arranged, the location of the semiconductor elements to be arranged, and the like.

In the case 3 in the semiconductor device 1 according to the present embodiment, as described above, the outer terminal portion 371 of the first main terminal 370 and the outer terminal portion 351 of the second main terminal 350 are arranged with a predetermined gap in the first direction (X direction) along the boundary between the terminal arrangement portion 306A and the housing portion 320 in the upper surface 301 of the single terminal arrangement portion 306A in the case member 300. As described above, in a case where the two outer terminal portions 351 and 371 having different potentials of applied voltages are arranged close to each other, from the viewpoint of miniaturization of the semiconductor device 1, it is preferable to further shorten a distance (gap) between the two outer terminal portions 351 and 371 within a range in which insulation is secured.

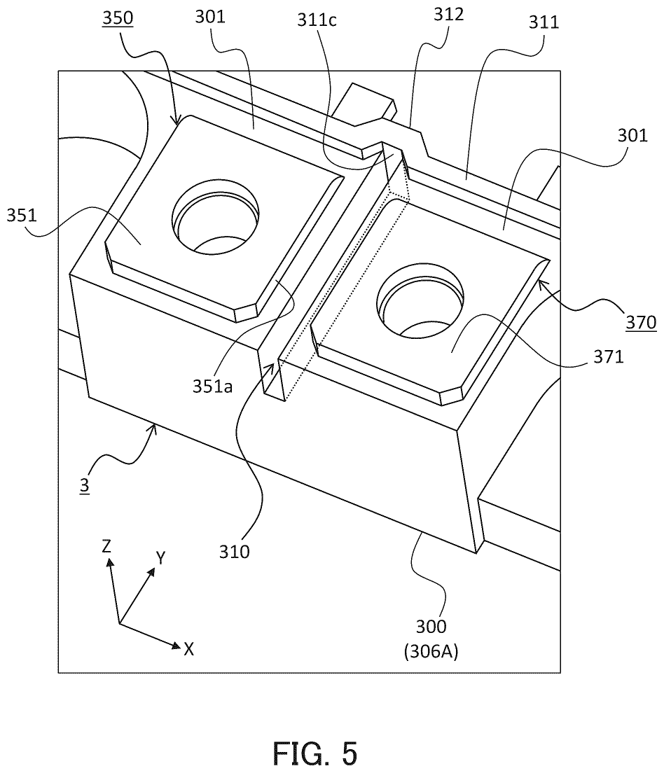

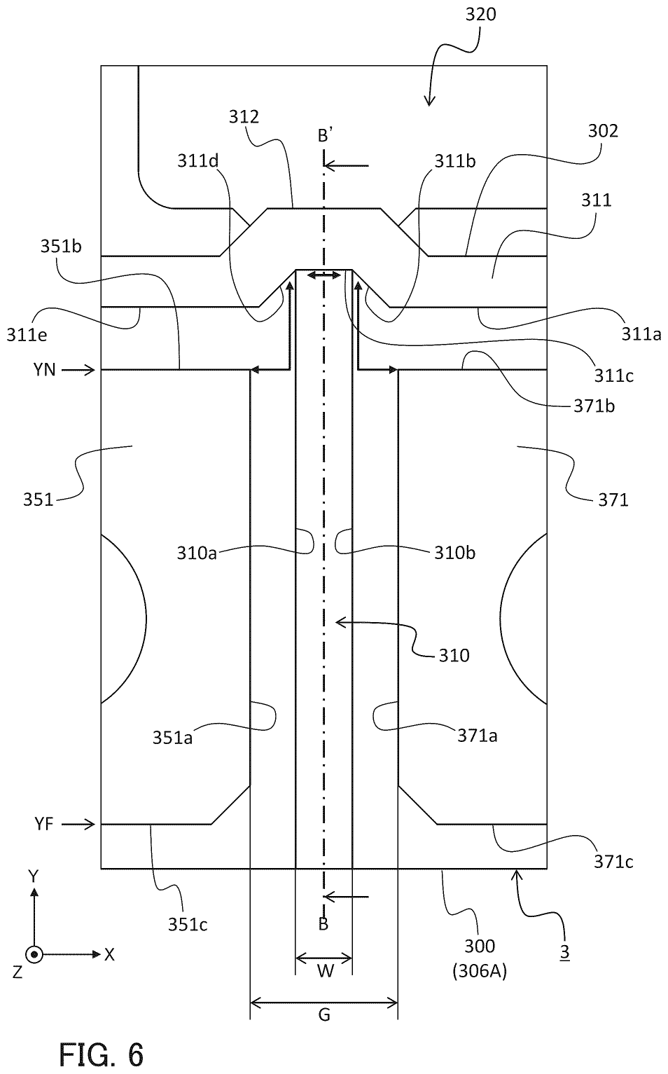

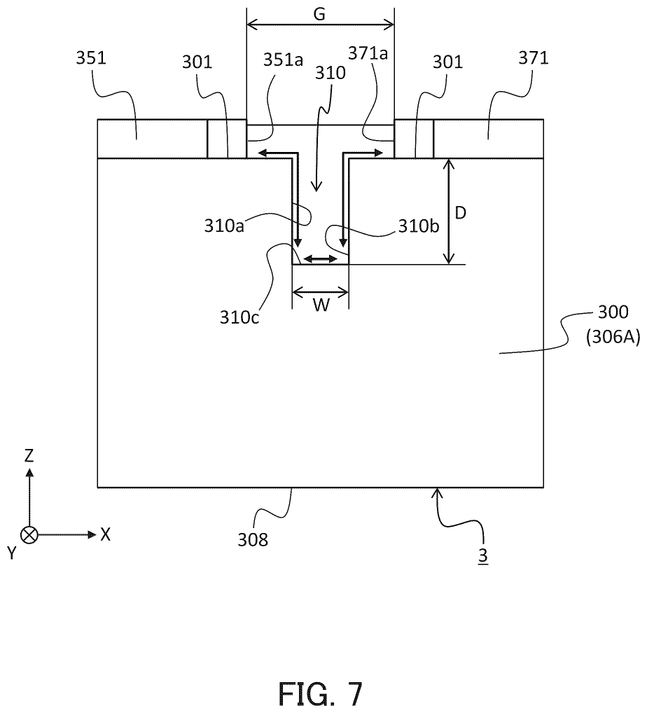

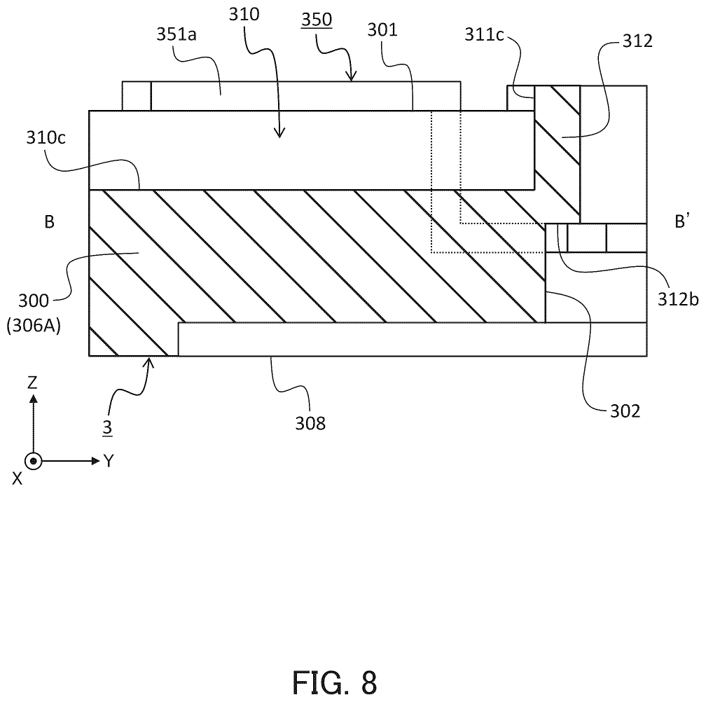

FIG. 5 is a perspective view for illustrating an example of a method for ensuring insulation between outer terminal portions in the case according to one embodiment. FIG. 6 is a top view illustrating a first example of a shape of a recess between outer terminal portions. FIG. 7 is a front view illustrating the first example of the shape of the recess between outer terminal portions. FIG. 8 is a cross-sectional side view illustrating the first example of the shape of the recess in the case taken along line B-B′ in FIG. 6. The cross-sectional side view of FIG. 8 illustrates a right side view of a portion on the left side of line B-B′ of the case 3 taken along line B-B′ of FIG. 6.

In the case 3 used in the semiconductor device 1 of the present embodiment, as illustrated in FIGS. 5 to 8, the recess 310 is formed in the gap portion between the outer terminal portion 371 of the first main terminal 370 and the outer terminal portion 351 of the second main terminal 350 on the upper surface 301 of the terminal arrangement portion 306A in the case member 300. The recess 310 is displaced in the direction from the upper surface 301 in which the outer terminal portions 351 and 371 are disposed to the lower surface 308, and extends in a second direction (Y direction) different from the first direction (X direction) in which the two outer terminal portions 351 and 371 are disposed in top view. One end of the recess 310 in the second direction is located closer to the housing portion 320 than positions YN of the end portions 351b and 371b of the outer terminal portions 351 and 371 close to the housing portion 320. The other end of the recess 310 in the second direction is located farther from the housing portion 320 than the positions YF of the end portions 351c and 371c of the outer terminal portions 351 and 371 far from the housing portion 320, and reaches a surface (not illustrated) of the terminal arrangement portion 306A opposite to the wall surface 302 facing the housing portion 320. The lower surface 308 illustrated in FIGS. 7 and 8 is an example of a second surface of the terminal arrangement portion 306A on the side opposite to the first surface (upper surface 301) on which the outer terminal portions 351 and 371 are arranged.

As described above, the housing portion 320 is filled with a sealing material for scaling the circuit board 2 and the like. Therefore, the recess 310 is formed such that the end close to the housing portion 320 in the second direction is separated from the housing portion 320 by the terminal arrangement portion 306A so that the sealing material filled in the housing portion 320 does not flow out into the recess 310. In the terminal arrangement portion 306A of the case member 300, a stepped portion 311 protruding upward (that is, a positive side in the Z direction which is a direction opposite to the lower surface) from the upper surface 301 is formed between the upper surface 301 on which the outer terminal portions 351 and 371 are arranged and the housing portion 320. In such a case, there are, for example, two types of creepage distances between the end portions 351b and 371b of the outer terminal portions 351 and 371, which are close to the housing portion 320, that is, a first creepage distance (see FIG. 7) along the first wall surface 310a, the bottom surface 310c, and the second wall surface 310b of the recess 310, and a second creepage distance (see FIG. 6) bypassing the upper end opening of the recess 310.

The first creepage distance along the recess 310 illustrated in FIG. 7 is the same as the creepage distance of each point in the facing side surfaces 351a and 371a of the outer terminal portions 351 and 371. Therefore, the depth D of the recess 310 is set to a value at which the first creepage distance G+2×D (G is a gap between the outer terminal portions 351 and 371) can ensure insulation between the outer terminal portions 351 and 371. In addition, when the recess 310 is formed, the second creepage distance (see FIG. 6) bypassing the upper end opening of the recess 310 described above is also desirably set to a value with which insulation between the outer terminal portions 351 and 371 can be secured. Therefore, in the case member 300 of the present embodiment, a protrusion 312 in which the terminal arrangement portion 306A protrudes toward the housing portion 320 is formed at a position where the recess 310 of the wall surface 302 of the terminal arrangement portion 306A facing the housing portion 320 is extended in the second direction. When the protrusion 312 is partially formed on the wall surface 302 of the terminal arrangement portion 306A, for example, the stepped portion 311 along the end of the upper surface 301 of the terminal arrangement portion 306A on the housing portion 320 side is formed to have side surfaces 311b, 311c, and 311d displaced toward the housing portion 320 between the side surface 311a facing the outer terminal portion 371 of the first main terminal 370 and the side surface 311e facing the outer terminal portion 351 of the second main terminal 350. As a result, in a state where the recess 310 of the terminal arrangement portion 306A and the housing portion 320 are separated from each other, the distance between the end portions 351b and 371b of the outer terminal portions 351 and 371, which are close to the housing portion 320, and one end of the recess 310 in the second direction can be increased. In addition, by partially forming the protrusion 312 on the wall surface 302 of the terminal arrangement portion 306A facing the housing portion 320, for example, it is possible to prevent an increase in the distance from the end portions 351b and 371b of the outer terminal portions 351 and 371 close to the housing portion 320 to the wall surface 302, and it is possible to prevent an increase in the size of the semiconductor device 1 in top view.

When the recess 310 described above is formed in the terminal arrangement portion 306A of the case member 300, the distance (width) W between the first wall surface 310a and the second wall surface 310b may be smaller than the distance (gap) G between the side surface 351a of the outer terminal portion 351 and the side surface 371a of the outer terminal portion 371, and for example, W can be set to about 1.5 mm.

In the semiconductor device 1 in which the recess 310 described above is formed in the terminal arrangement portion 306A of the case member 300, it is possible to reduce a decrease in the creepage distance due to shortening of the distance (gap) G between the main terminals to which voltages having different potentials are applied, and it is possible to further downsize the semiconductor device 1 while ensuring the insulation dependent on the creepage distance. Specifically, it is possible to further downsize the semiconductor device 1 while ensuring the insulation dependent on the creepage distance as compared with a semiconductor device having a gap large enough to sufficiently ensure the insulation dependent on the creepage distance between adjacent terminals as in JP 09-232512A.

In addition, in the case 3 of the semiconductor device 1 described above, the outer terminal portion 371 of the first main terminal 370 and the outer terminal portion 351 of the second main terminal 350, which can be input ends, and the outer terminal portion 331 of the third main terminal 330, which can be output ends, are arranged so as to be in a positional relationship with the housing portion 320 in which the circuit board 2 is housed interposed therebetween in top view. Therefore, the semiconductor device 1 according to the present embodiment can reduce the deviation of the planar shape (in particular, the aspect ratio) in top view as compared with the case where the three electrode plates of JP 01-144662A and the three external wiring connection terminals of JP 2014-183196A are arranged side by side in one direction on the upper surface of the lid body, for example. In addition, as compared with the case where the surfaces of the lid body in which the two external wiring connection terminals are disposed are connected at the positions where the side surfaces of the two external wiring connection terminals face each other as in JP 2014-183196A, it is possible to shorten the gap between the external wiring connection terminals which can ensure the insulation dependent on the creepage distance. Therefore, the semiconductor device 1 of the present embodiment can have a higher degree of freedom in terms of an installation place and an installation direction, for example, than the semiconductor devices of JP 01-144662A and JP 2014-183196A. In addition, as compared with the case where the three electrode plates are arranged side by side in one direction on the upper surface of the lid body, the work of connecting the terminal of the power supply cable, the bus bar, and the like to the outer terminal portion of each main terminal is facilitated.

Furthermore, the terminal arrangement portion 306A of the case 3 described above with reference to FIGS. 5 to 8 includes the protrusion 312 protruding toward the housing portion 320 at a position extending one end of the recess 310 in the extending direction (Y direction). For example, as illustrated in FIG. 8, the protrusion 312 is formed such that a lower end 312b is positioned above the lower surface 308 of the terminal arrangement portion 306A. In this way, for example, the second creepage distance bypassing the recess 310 can be increased without increasing the dimension of the housing portion 320 required when the circuit board 2 is housed in the housing portion 320 from the lower surface side of the case member 300 including the lower surface 308 of the terminal arrangement portion 306A. For this reason, for example, as compared with the configuration in which the thermosetting epoxy resin protrudes on the recess side where the insulating wall is provided as in JP 2002-164503A, the creepage distance in top view can be made long, and the insulation dependent on the creepage distance can be easily secured.

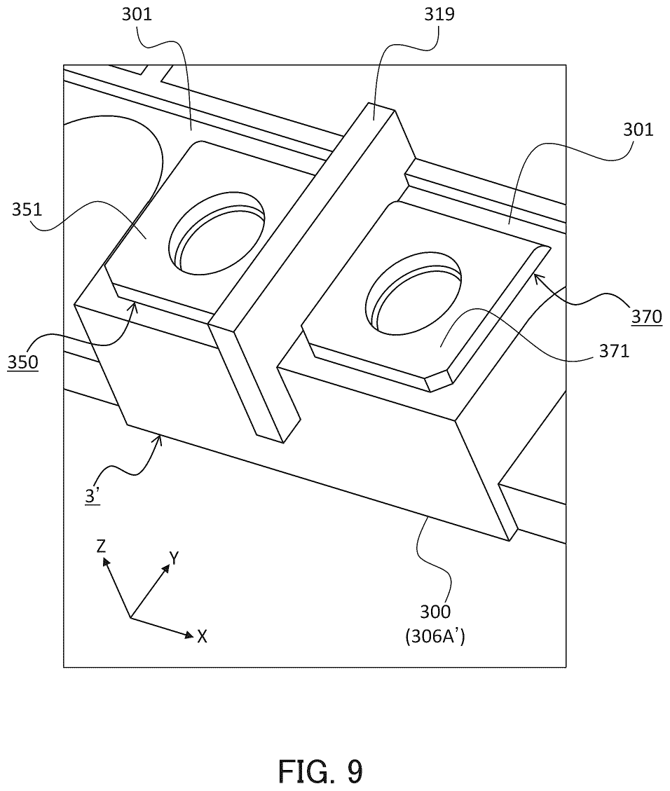

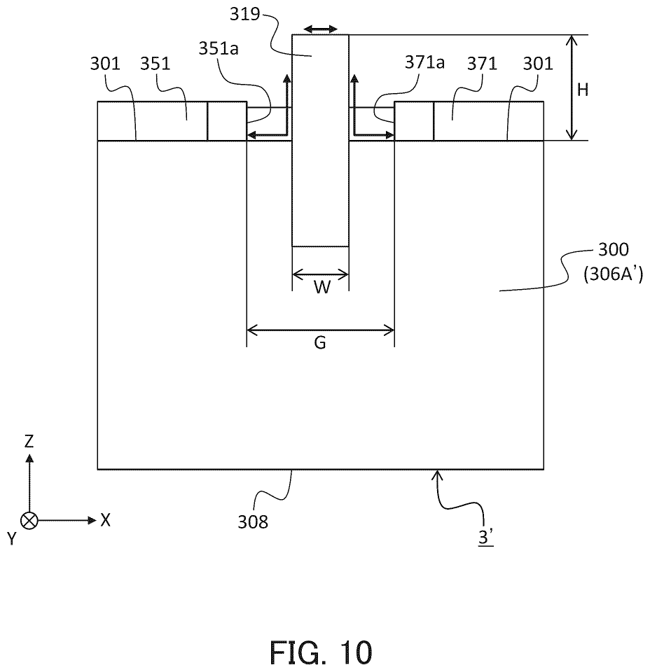

FIG. 9 is a perspective view illustrating a conventional example of a case in which a creepage distance is increased. FIG. 10 is a front view of a portion of the case illustrated in FIG. 9.

In a terminal arrangement portion 306A′ of a case 3′ illustrated in FIGS. 9 and 10, a wall portion 319 is formed between the outer terminal portion 371 of the first main terminal 370 and the outer terminal portion 351 of the second main terminal 350 on the upper surface 301 instead of the recess 310 described above. In a case where such a wall portion 319 is formed, assuming that the height of the wall portion 319 from the upper surface 301 is H, the creepage distance between the side surface 351a of the outer terminal portion 351 and the side surface 371a of the outer terminal portion 371 facing each other across the wall portion 319 is a distance G+2×H. Therefore, the creepage distance can be increased by increasing the height H of the wall portion 319.

However, in the case 3′ having the wall portion 319 illustrated in FIGS. 9 and 10, the distance (dimension in the Z direction) from the lower surface 308 of the terminal arrangement portion 306A′ to the upper end surface of the wall portion 319 becomes long. Therefore, the degree of freedom regarding the installation place and the installation direction of the semiconductor device using the case 3′ is lower than that of the semiconductor device 1 according to the present embodiment. In addition, since the wall portion 319 close to the outer terminal portion 371 of the first main terminal 370 and the outer terminal portion 351 of the second main terminal 350 is provided, for example, the work of connecting a terminal, a bus bar, or the like of the power supply cable to these outer terminal portions may be difficult. Furthermore, when the heated insulating resin is poured into a mold having a space corresponding to the thin wall portion 319 extending upward from the upper surface 301 at the time of manufacturing (forming) the case 3′, distortion or voids may occur in a portion of the wall portion 319.

On the other hand, in the case 3 of the present embodiment, since the creepage distance is secured by the recess 310, the dimension in the Z direction can be reduced as compared with the case where the wall portion 319 is formed, and the degree of freedom regarding the installation place and the installation direction can be increased. In addition, since the wall portion 319 close to the outer terminal portion 371 of the first main terminal 370 and the outer terminal portion 351 of the second main terminal 350 is eliminated, the work of connecting a terminal, a bus bar, or the like of the power supply cable to the outer terminal portions is facilitated. Furthermore, it is possible to reduce the occurrence of distortion and voids when the case 3 is manufactured. In addition, by forming the recess 310 instead of the wall portion 319, the amount of the insulating material required for manufacturing the case member 300 can be reduced.

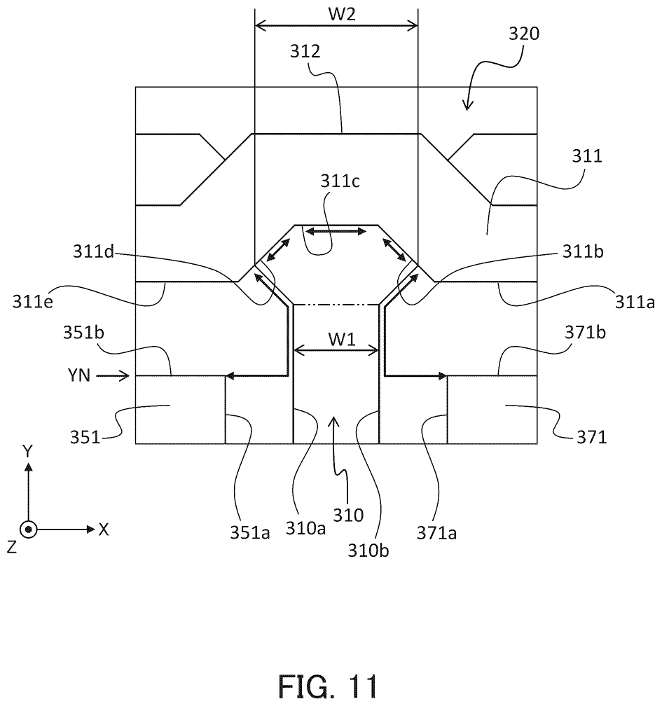

Note that the shape of the recess 310 of the case 3 according to the present embodiment is not limited to the shape described above with reference to FIGS. 5 to 8. The shape of the recess 310 may be, for example, any shape as described below with reference to FIGS. 11 to 16, or may be a combination of some shapes.

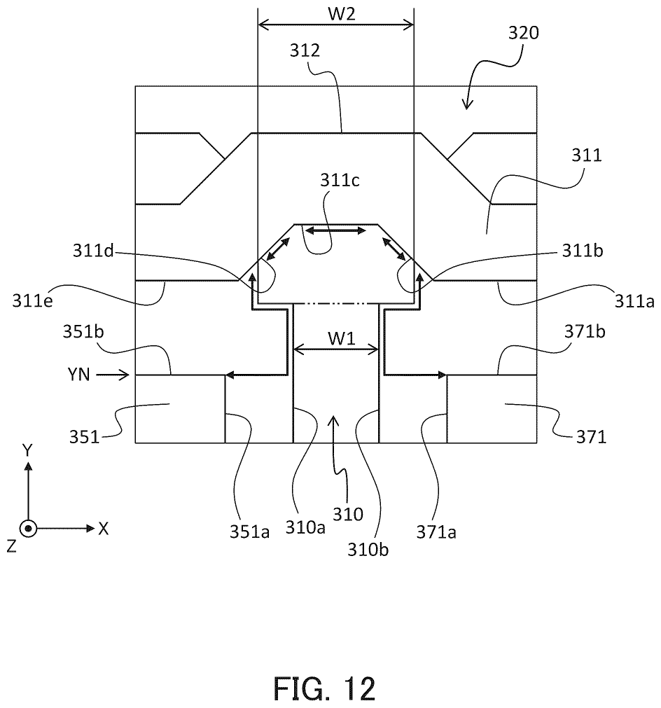

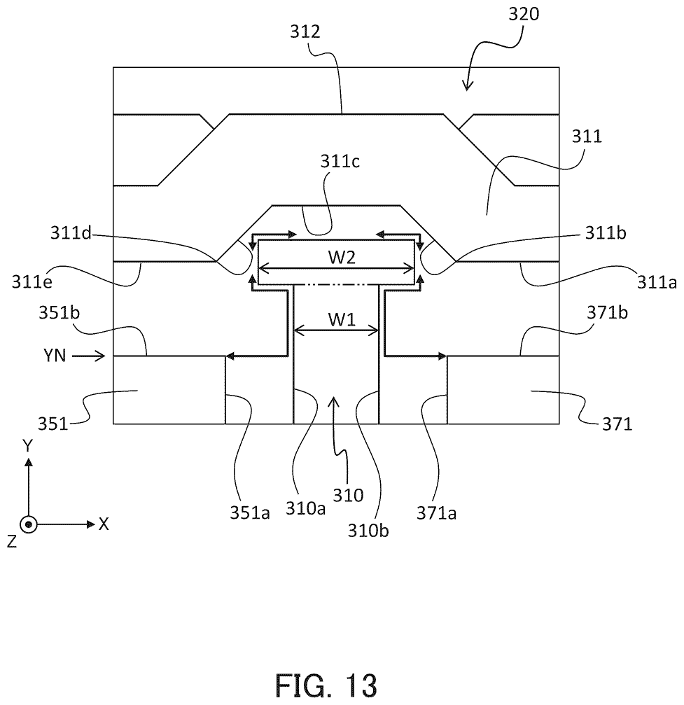

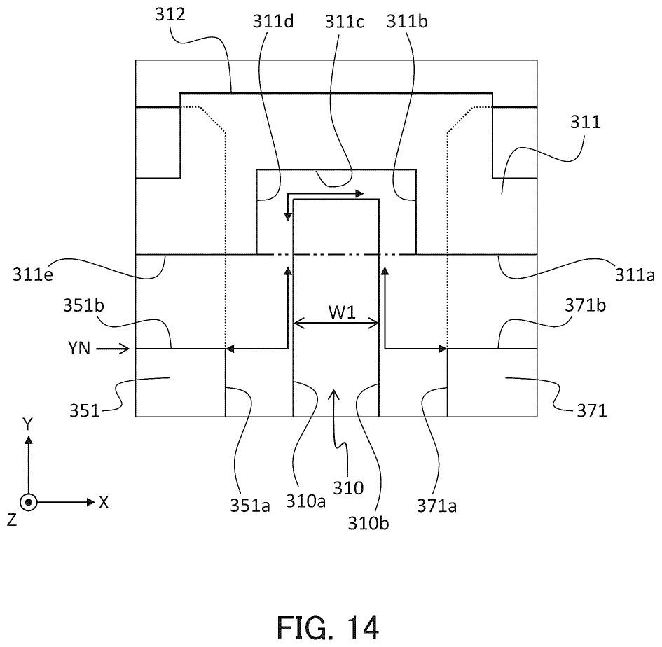

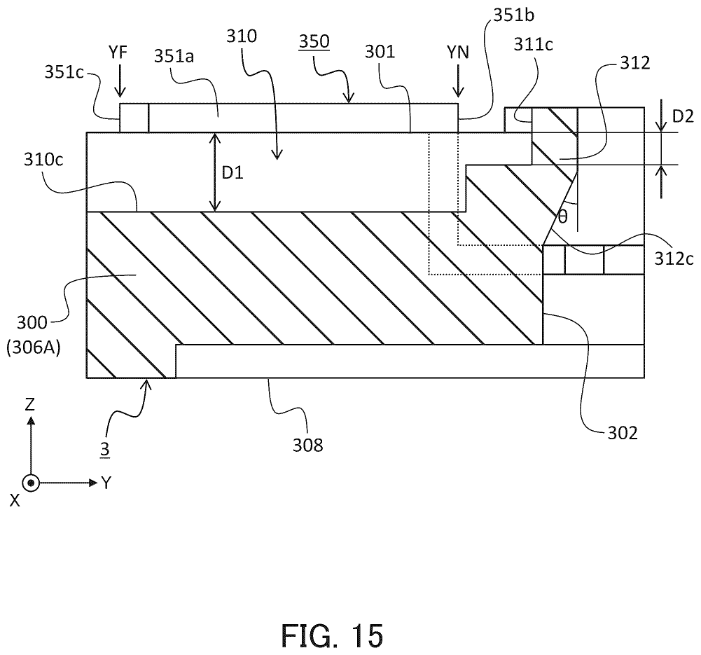

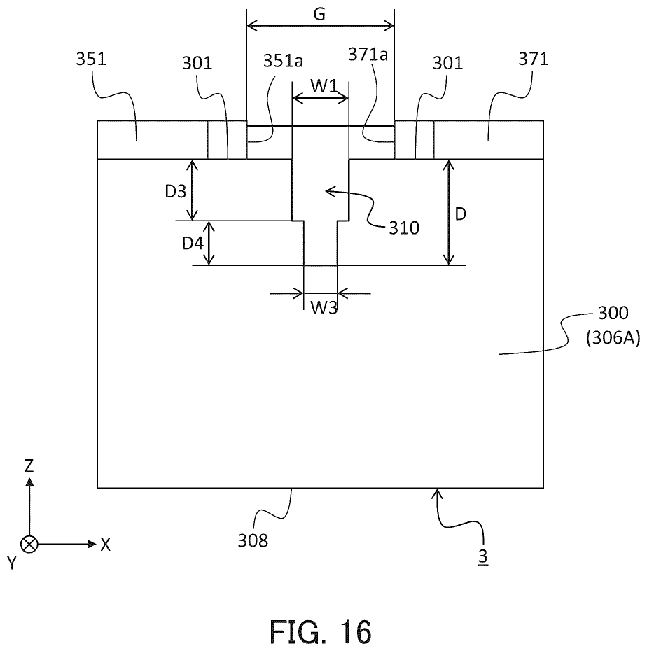

FIG. 11 is a top view for illustrating a first modification of the recess. FIG. 12 is a top view for illustrating a second modification of the recess. FIG. 13 is a top view for illustrating a third modification of the recess. FIG. 14 is a top view for illustrating a fourth modification of the recess. FIG. 15 is a side cross-sectional view for illustrating another modification of the recess. FIG. 16 is a front view illustrating still another modification of the recess. FIGS. 11 to 14 respectively illustrate only an end portion of the recess 310 on the housing portion 320 side and its periphery in the terminal arrangement portion 306A of the case member 300. FIG. 15 corresponds to the right side view of the portion on the left side of line B-B′ in the case 3 cut along line B-B′ in FIG. 6.

The recess 310 of the case 3 illustrated in FIGS. 11 and 12 has, at the end portion on the housing portion 320 side in top view, a section in which the width is wider than the width W1 of the portion farther from the housing portion 320 than the positions YN of the ends 371b and 351b of the outer terminal portion 371 of the first main terminal 370 and the outer terminal portion 351 of the second main terminal 350 close to the housing portion 320. The end portion of the recess 310 exemplified in FIG. 11 has a width that continuously increases from the end of the section of the width W1 viewed in the extending direction (Y direction) of the recess 310 in top view toward the housing portion 320 side and becomes a maximum width W2. The end portion of the recess 310 illustrated in FIG. 12 fluctuates from the width W1 to the maximum width W2 at the end of the section of the width W1 as viewed in the extending direction (Y direction) of the recess 310 in top view. As described above, by providing a section, which is wider than the width W1 of the section passing between the outer terminal portion 371 of the first main terminal 370 and the outer terminal portion 351 of the second main terminal 350 facing each other, at the end portion of the recess 310 on the housing portion 320 side, the second creepage distance bypassing the recess 310 between the outer terminal portion 351 and the outer terminal portion 371 can be further increased.

In the recess 310 of the case 3 illustrated in FIGS. 5 and 6 and FIGS. 11 and 12, the end portion on the housing portion 320 side reaches the side surfaces 311b to 311d of the stepped portion 311. In other words, in the terminal arrangement portion 306A of the case 3 described above, the upper surface 301 on which the outer terminal portion 371 is arranged and the upper surface 301 on which the outer terminal portion 351 is arranged are separated by the recess 310. However, for example, as illustrated in FIG. 13, the end portion of the recess 310 on the housing portion 320 side may not reach the side surfaces 311b to 311d of the stepped portion 311. In the recess 310 illustrated in FIG. 13, the width W2 of the end portion on the housing portion 320 side in top view is wider than the width W1 of the section passing between the outer terminal portion 371 of the first main terminal 370 and the outer terminal portion 351 of the second main terminal 350 facing each other. Therefore, even when the end portion of the recess 310 on the housing portion 320 side does not reach the side surfaces 311b to 311d of the stepped portion 311, the second creepage distance bypassing the recess 310 can be increased.

In addition, in a case where the second creepage distance of the outer terminal portion 351 and the outer terminal portion 371 bypassing the recess 310 is made long, for example, as illustrated in FIG. 14, a shape of a portion of the stepped portion 311 protruding toward the housing portion 320 in a top view may be a rectangular wave shape. FIG. 14 illustrates an example in which in the terminal arrangement portion 306A, the upper surface 301 on which the outer terminal portion 371 is arranged and the upper surface 301 on which the outer terminal portion 351 is arranged are continuous along the rectangular wave-shaped portion of the stepped portion 311, but the two upper surfaces 301 may be separated by the recess 310. In addition, the rectangular wave-shaped portion in the stepped portion 311 may be, for example, a surface in which the side surface 311b extends from the second wall surface 310b of the recess 310, and a surface in which the side surface 311d extends from the first wall surface 310a of the recess 310. Furthermore, although not illustrated, the shape of the portion of the stepped portion 311 protruding toward the housing portion 320 in top view may be another shape, for example, a triangular wave shape or an arc shape.

FIG. 15 illustrates the recess 310 in which the relationship between the depth D1 of the section passing between the side surface 351a of the outer terminal portion 351 and the side surface 371a of the outer terminal portion 371 facing each other and the depth D2 of the section closer to the housing portion 320 than the section is D1>D2. The depth D1 corresponds to the depth D associated with the first creepage distance along the first wall surface 310a, the bottom surface 310c, and the second wall surface 310b of the recess 310 described above with reference to FIG. 7. On the other hand, as described above with reference to FIG. 6 and the like, the second creepage distance bypassing the recess 310 of the terminal arrangement portion 306A is associated with the insulation between the outer terminal portions 351 and 371 in the housing portion 320 with respect to the position YN of the end portion of the outer terminal portions 351 and 371 on the housing portion 320 side in the extending direction of the recess 310. Therefore, the depth D2 of the recess 310 in the section closer to the housing portion 320 than the position YN in the extending direction of the recess 310 may not be the same as the depth D1 in the section farther from the housing portion 320 than the position YN. When the recess 310 satisfying D1>D2 (>0) is formed as illustrated in FIG. 15, for example, deformation of the case member 300 (terminal arrangement portion 306A) in the portion where the recess 310 is formed can be reduced. In the recess 310, for example, the depth of a section farther from the housing portion 320 than the position YF of the end portions of the outer terminal portions 351 and 371 far from the housing portion 320 may be made smaller than the depth D1 associated with the first creepage distance, similarly to the housing portion 320 side than the position YN.

In addition, in the case 3 illustrated in FIG. 15, the protrusion 312 protruding toward the housing portion 320 in the wall surface 302 of the terminal arrangement portion 306A includes an inclined surface 312c inclined at an angle θ with respect to the vertical direction (Z direction) so that the lower end of the protrusion 312 is in contact with the wall surface 302 at an obtuse angle. In the protrusion 312 of the case 3 illustrated in FIG. 8, the lower end 312b and the wall surface 303 are in contact with each other at a right angle. Therefore, when the housing portion 320 is filled with the sealing material, a filling defect (void) may occur at a connection portion between the lower end 312b of the protrusion 312 and the wall surface 302. On the other hand, in the case 3 illustrated in FIG. 15, since the lower end portion of the protrusion 312 and the wall surface 302 are connected at an obtuse angle, it is possible to reduce occurrence of a filling defect (void) at a connection portion between the inclined surface 312c of the protrusion 312 and the wall surface 302 when the sealing material is injected into the housing portion 320. Note that the angle θ of the inclined surface 312c is not limited to a specific angle. Further, the inclined surface 312c of the protrusion 312 may extend over the entire region from the upper end to the lower end. Further, the protrusion 312 may be configured of, for example, a curved surface protruding toward the housing portion 320.

Further, the shape of the recess 310 is not limited to a shape having a single width from the upper end (open end) to the bottom surface 310c. For example, as illustrated in FIG. 16, the recess 310 may have a shape having the width W1 from the upper end to a depth D3 and a width W3 (<W1) from the depth D3 to a depth D4. The width of this type of recess 310 is not limited to two, and may be three or more.

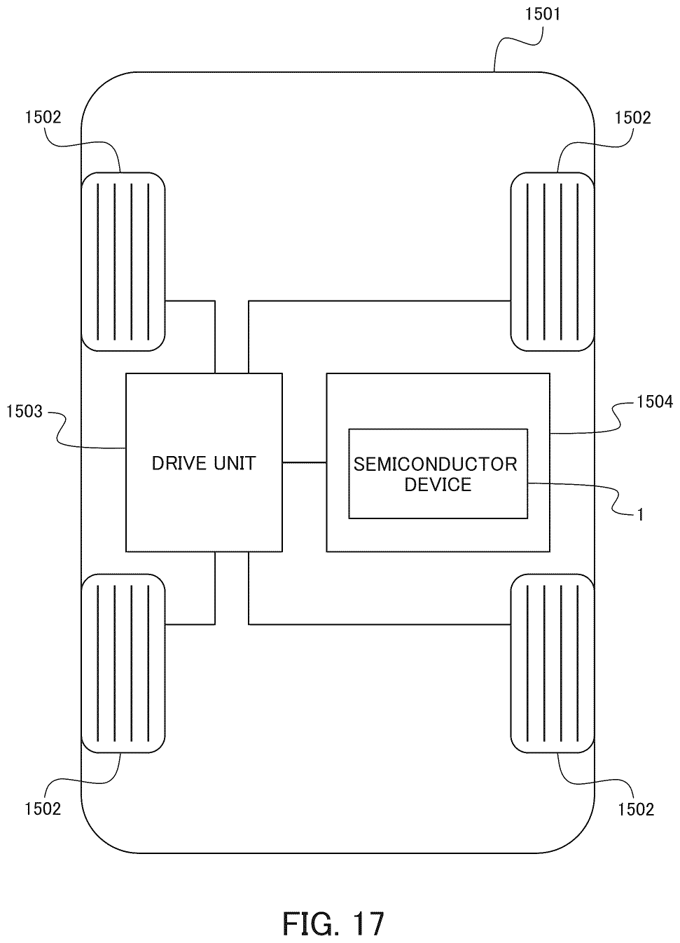

The semiconductor device 1 according to the above embodiment is not limited to a specific application. However, in particular, the semiconductor device 1 including the cooler 9 is suitable for use in a high-temperature environment. For example, the semiconductor device 1 according to the above embodiment can be applied to a power conversion device such as an inverter device of an in-vehicle motor or the like. A vehicle to which the semiconductor device 1 according to the present invention is applied is described with reference to FIG. 17.

FIG. 17 is a schematic plan view illustrating an example of the vehicle to which the semiconductor device according to the present invention is applied. A vehicle 1501 illustrated in FIG. 17 includes, for example, a four-wheeled vehicle including four wheels 1502. The vehicle 1501 may be, for example, an electric vehicle that drives wheels by a motor or the like, or a hybrid vehicle using power of an internal combustion engine in addition to the motor. Furthermore, the vehicle to which the semiconductor device 1 is applied is not limited to a four-wheeled vehicle, and may be a two-wheeled vehicle, a railway vehicle, or the like.

The vehicle 1501 includes a drive unit 1503 that applies power to the wheels 1502 and a control device 1504 that controls the drive unit 1503. The drive unit 1503 may include, for example, at least one of an engine, the motor, and a hybrid of the engine and the motor.

The control device 1504 controls (for example, power control) the drive unit 1503. The control device 1504 includes the semiconductor device 1 including the cooler 9 according to the above-described embodiment. The semiconductor device 1 can be configured to perform power control on the drive unit 1503.

The embodiments of the semiconductor device 1 according to the present invention are not limited to the above embodiments, and various changes, substitutions, and modifications may be made without departing from the spirit of the technical idea. Further, when the technical idea can be realized in another manner by the progress of the technology or another derived technology, the technical idea may be carried out by using a method thereof. Hence, the claims cover all embodiments that may be included within the scope of the technical idea.

In the following, feature points in the above embodiment are summarized.

A semiconductor device according to the above-described embodiment includes: a circuit board in which a semiconductor element is disposed on an interconnect plate; a case member having a housing portion in which the circuit board is housed; and a plurality of main terminals each having an outer terminal portion exposed to a terminal arrangement portion of the case member and an inner terminal portion electrically connected to a conductor of the circuit board in the housing portion of the case member, in which
the case member has a shape in which the terminal arrangement portion and the housing portion are adjacent to each other in a plan view of a first surface of the terminal arrangement portion on which the outer terminal portion is disposed, and
the plurality of main terminals includes: a first main terminal and a second main terminal, the outer terminal portions of which are arranged with a predetermined gap in a first direction along a boundary between the terminal arrangement portion and the housing portion in a plan view of the first surface of the case member,
the terminal arrangement portion of the case member includes
a recess that is displaced from the first surface in a direction of a second surface opposite to the first surface between the outer terminal portion of the first main terminal and the outer terminal portion of the second main terminal in the first surface, and extends in a second direction different from the first direction in a plan view of the first surface, and one end of the recess in the second direction being located closer to the housing portion than an end portion of the outer terminal portion of the first main terminal and an end portion of the outer terminal portion of the second main terminal, which are close to the housing portion, the other end of the recess in the second direction being located farther from the housing portion than an end portion of the outer terminal portion of the first main terminal and an end portion of the outer terminal portion of the second main terminal, which are far from the housing portion; and
a protrusion that protrudes toward the housing portion at a position obtained by extending the one end of the recess in a wall surface facing the housing portion in the second direction and separates the recess and the housing portion.

In the semiconductor device according to the above-described embodiment, the terminal arrangement portion of the case member includes a stepped portion protruding from the first surface in a direction opposite to the second surface along a boundary between the terminal arrangement portion and the housing portion, between the first surface and the housing portion, and the stepped portion has a position obtained by extending the one end of the recess in a surface facing the outer terminal portion side in the second direction and displaced toward the housing portion.

In the semiconductor device according to the above-described embodiment, the recess has the one end reaching a position of the surface of the stepped portion facing the outer terminal portion side in the plan view of the first surface.

In the semiconductor device according to the above-described embodiment, the recess includes a section, which is closer to the housing portion than end portions of the outer terminal portion of the first main terminal and the outer terminal portion of the second main terminal close to the housing portion and in which the distance in the first direction is longer than that of a first section, which is farther from the housing portion than the end portions of the outer terminal portion of the first main terminal and the outer terminal portion of the second main terminal close to the housing portion.

In the semiconductor device according to the above-described embodiment, in the first surface of the terminal arrangement portion, a region where the outer terminal portion of the first main terminal is arranged and a region where the outer terminal portion of the second main terminal is arranged are separated by the recess.

In the semiconductor device according to the above-described embodiment, in the first surface of the terminal arrangement portion, a region where the outer terminal portion of the first main terminal is arranged is continuous with a region where the outer terminal portion of the second main terminal is arranged via a region located closer to the housing portion than the one end of the recess.

In the semiconductor device according to the above-described embodiment, the recess includes a section, which is closer to the housing portion than end portions of the outer terminal portion of the first main terminal and the outer terminal portion of the second main terminal closer to the housing portion and in which the depth from the first surface is shallower than that of a first section, which is farther from the housing portion than the end portions of the outer terminal portion of the first main terminal and the outer terminal portion of the second main terminal closer to the housing portion.

In the semiconductor device according to the above-described embodiment, in the circuit board, the semiconductor element is housed in the housing portion in a direction closer to the first surface of the terminal arrangement portion than the interconnect plate, and in the case member, an end of a portion protruding toward the housing portion by the protrusion in the wall surface facing the housing portion, which is close to the second surface, is located closer to the first surface than the surface of the interconnect plate on which the semiconductor element is disposed.

In the semiconductor device according to the above-described embodiment, in the case member, a protruding amount of the portion protruding toward the housing portion by the protrusion in the wall surface facing the housing portion decreases from the first surface toward the second surface.

In the semiconductor device according to the above-described embodiment, the circuit board is formed with an inverter circuit having a first input end, a second input end, and an output end, the first main terminal is electrically connected to the first input end of the inverter circuit, and the second main terminal is electrically connected to the second input end of the inverter circuit.

In the semiconductor device according to the above-described embodiment, the case member includes a terminal arrangement portion in which a third main terminal electrically connected to the output end is arranged on a side opposite to the terminal arrangement portion in which the first main terminal and the second main terminal are arranged with the housing portion interposed therebetween.

In the semiconductor device according to the above-described embodiment, the case member has a substantially annular shape in which a hollow portion in which the first surface side and the second surface side are opened is the housing portion.

The semiconductor device according to the above embodiment further includes a cooler thermally connected to a surface of the interconnect plate opposite to a surface on which the semiconductor element is disposed.

The vehicle according to the above-described embodiment includes the semiconductor device according to the above-described embodiment.

As described above, the present invention has an effect that the semiconductor device can be further downsized while securing the insulation dependent on the creepage distance, and is particularly useful for an industrial or electrical semiconductor device used as a power conversion device, and a vehicle.

What is claimed is:

1. A semiconductor device comprising:
a circuit board, including:
an interconnect plate, and
a semiconductor element disposed on the interconnect plate;
a case member, having:
a housing portion in which the circuit board is disposed, and
a terminal arrangement portion, which is adjacent to the housing portion in a plan view of the semiconductor device, the terminal arrangement portion having:
a first surface and a second surface opposite to each other, and
a wall surface facing the housing portion; and
a plurality of main terminals, each having:
an outer terminal portion exposed from the terminal arrangement portion, and
an inner terminal portion electrically connected to the circuit board, wherein
the plurality of main terminals includes a first main terminal and a second main terminal, the outer terminal portions of which are arranged with a predetermined gap therebetween in a first direction; and
the terminal arrangement portion of the case member includes:
a recess that is formed in the first surface thereof between the outer terminal portion of the first main terminal and the outer terminal portion of the second main terminal, and that extends in a second direction different from the first direction, wherein in the second direction,
each of the outer terminal portions has a first end portion and a second end portion, the first end portion being closer to the housing portion than the second end portion, and
the recess has a first end and a second end, the first end being closer to the housing portion than the second end thereof, and than the first end portion of the outer terminal portion of the first main terminal and the first end portion of the outer terminal portion of the second main terminal, and the second end being farther from the housing portion than the second end portion of the outer terminal portion of the first main terminal and the second end portion of the outer terminal portion of the second main terminal; and
a protrusion formed on the wall surface thereof toward the housing portion, the protrusion being aligned with the recess in the second direction and separating the recess and the housing portion.

2. The semiconductor device according to claim 1, wherein
the terminal arrangement portion of the case member includes a stepped portion protruding from the wall surface to thereby form the protrusion.

3. The semiconductor device according to claim 2, wherein the first end of the recess reaches a surface of the stepped portion.

4. The semiconductor device according to claim 1, wherein
the recess includes an end section that is located between the housing portion and the first end portions of the outer terminal portions of the first and second main terminals in the second direction, and
a width of the end section in the first direction is larger than that of a section of the recess other than the end section.

5. The semiconductor device according to claim 1, wherein the first surface of the terminal arrangement portion has
a first region in which the outer terminal portion of the first main terminal is arranged, and
a second region in which the outer terminal portion of the second main terminal is arranged,
the first and second regions being separated by the recess.

6. The semiconductor device according to claim 1, wherein the first surface of the terminal arrangement portion includes
a first region in which the outer terminal portion of the first main terminal is arranged,
a second region in which the outer terminal portion of the second main terminal is arranged, and
a third region connecting the first region and the second region, the third region being located closer to the housing portion than the first end of the recess.

7. The semiconductor device according to claim 1, wherein
the recess includes an end section that is located between the housing portion and the first end portions of the outer terminal portions of the first and second main terminals in the second direction, and
in a thickness direction of the semiconductor device, a depth of the end section from the first surface is shallower than that of a section of the recess other than the end section.

8. The semiconductor device according to claim 1, wherein in a thickness direction of the semiconductor device,
the semiconductor element is disposed closer to the first surface of the terminal arrangement portion than the interconnect plate, and
the protrusion is located closer to the first surface than the interconnect plate.

9. The semiconductor device according to claim 8, wherein a protruding amount of the protrusion decreases in the thickness direction of the semiconductor device.

10. The semiconductor device according to claim 1, wherein
the circuit board is formed with an inverter circuit having a first input end, a second input end, and an output end, and
the first main terminal is electrically connected to the first input end of the inverter circuit, and the second main terminal is electrically connected to the second input end of the inverter circuit.

11. The semiconductor device according to claim 10, wherein
the plurality of main terminals further includes a third main terminal,
the third main terminal, and the first and second main terminals, are arranged with the housing portion interposed therebetween, and
the third main terminal is electrically connected to the output end of the inverter circuit.

12. The semiconductor device according to claim 1, wherein the case member has a substantially annular shape, a hollow portion thereof forming the housing portion.

13. The semiconductor device according to claim 1, further comprising a cooler thermally connected to a first surface of the interconnect plate, which is opposite to a second surface of the interconnect plate on which the semiconductor element is disposed.

14. A vehicle comprising the semiconductor device according to claim 1.
